(19) United States
(12) Patent Application Publication
(10) Pub. No.: US 2004/0036495 A1
(43) Pub. Date: Feb. 26, 2004

(54) Electromigration test structure for detecting the reliability of wiring

(76) Inventors: Josef Fazekas, Munchen (DE); Andreas Martin, Munchen (DE); Jochen Von Hagen, Kolbermoor (DE)

Correspondence Address: LERNER AND GREENBERG, P.A., Post Office Box 2480, Hollywood, FL, 33022-2480, US

(21) Appl. No.: 10/647,615

(22) Filed: Aug. 25, 2003

Related U.S. Application Data
(63) Continuation of application No. PCT/DE01/04599, filed on Dec. 7, 2001.

(30) Foreign Application Priority Data
Feb. 23, 2001 (DE) 101 08 915.5

(51) Int. Cl. G01R 31/26

(52) U.S. Cl. 324/765

(57) ABSTRACT

An electromigration test structure detects the reliability of wirings. A region to be tested has an electromigration region and an electromigration barrier region formed between first and second test structure terminal regions. In order to estimate a service life in a manner that is highly accurate and suitable for highly accelerated tests, a first and third sensor terminal are situated in direct proximity to the electromigration barrier region, and a second sensor terminal is situated at the second test structure terminal region.

### CROSS-REFERENCE TO RELATED APPLICATION

This application is a continuation of copending International Application No. PCT/DE01/04599, filed Dec. 7, 2001, which designated the United States and was not published in English.

### BACKGROUND OF THE INVENTION

### Field of the Invention

The present invention relates to an electromigration test structure for detecting the reliability of wirings, and in particular to an electromigration test structure for highly accelerated tests in semiconductor circuits.

A high reliability particularly in integrated semiconductor circuits but also in thin-film technology constitutes a significant factor in production and in later use. Therefore, a multiplicity of tests are carried out during production in order to be able to provide a statement that is as accurate as possible with regard to the quality of a respective production process.

Furthermore, since a structure width of wirings, particularly in semiconductor circuits, is increasingly reduced as the integration density progressively increases, interconnects of this type, in large scale integrated circuits, are loaded with very high current densities during operation. In this case, the interconnects do not melt on account of good cooling by virtue of the basic material or substrate used. Instead, the current gives rise to a material transport in the electron direction, which can lead to the failure of the circuit through formation of holes in the interconnects. This mechanism is dependent on current density and temperature and is usually called electromigration. Electromigration determines, inter alia, a maximum service life or a reliability of a respective circuit and can be influenced by various parameters in production.

In order, therefore, to be able to estimate a maximum service life of semiconductor circuits or thin-film circuits, so-called electromigration tests are carried out which take place at elevated temperatures and current densities on specific test structures. The elevated temperatures are usually realized in special furnaces, whereby an accelerated artificial ageing process can be brought about. However, since the production of integrated semiconductor circuits, in particular, can last for several weeks and it is desirable to check for possibly defective structures during production itself, so-called accelerated and highly accelerated tests have been developed which enable a deviation in production in regular monitoring measurements. The measurements must proceed on the seconds scale in this case in order not to increase the production time and hence the production costs.

More extensive acceleration is possible, however, only by way of very high temperatures and corresponding current densities, self-heating being effected by way of the high current.

The literature reference by H. A. Schafft, titled “Reliability Test Chips: NIST33 & 34 for JEDEC Inter-Laboratory Experiments and More”, IEEE International Integrated Reliability Workshop Final Report, page 144 et seq., 1997, discloses an electromigration test structure for detecting the reliability of wirings by performing highly accelerated tests, an electromigration region to be tested in the form of a metallic interconnect between a first and second test structure terminal region being known. In order to check for a failure, a first and second sensor terminal leading to an associated sensor pad are respectively situated at the test structure terminal regions. Using the JEDEC standard test method such as e.g. the isothermal test (JESD63) and the so-called SWEAT test (JEP119), it is thus possible to make service life estimations for the associated semiconductor circuits. What is disadvantageous about such test structures, however, is that they have only little production relevance since, in semiconductor circuits, use is usually made of so-called electromigration barriers for example in the form of contacts (vias) between conductive layers, which cannot be checked, or cannot be checked adequately, by test structures of this type.

The literature reference by T. S. Sriram, titled “Electromigration Teststructure Designs to identify VIA failure modes”, Proc. International Conference on Microelectronic Teststructures, pp. 155 to 157, 2000, discloses a further conventional electromigration test structure for detecting the reliability of wirings in highly accelerated tests, the region to be tested of the electromigration test structure having both an electromigration region in the form of a metallic interconnect and an electromigration barrier in the form of a contact (via). Although an improved product relevance or improved meaningfulness for the associated semiconductor circuit is obtained in this way, highly accurate quantitative statements particularly with regard to the temperature are not possible.

### SUMMARY OF THE INVENTION

It is accordingly an object of the invention to provide an electromigration test structure for detecting the reliability of wiring that overcomes the above-mentioned disadvantages of the prior art devices of this general type, which can be used to realize a further acceleration of a test with improved test accuracy.

With the foregoing and other objects in view there is provided, in accordance with the invention, an electromigration test structure for detecting the reliability of wirings. The electromigration test structure contains first and second test structure terminal regions for impressing a heating current, and a region to be tested having an electromigration region with a constant material flow and an electromigration barrier region with a reduced material flow. The region to be tested is connected between the first and second structure terminal regions. The electromigration region is structured for producing a substantially homogeneous temperature distribution therein. First and second sensor terminals are coupled to and detect a failure of the region to be tested. A third sensor terminal for detecting a temperature of the electromigration region is connected to the electromigration region in direct proximity to the electromigration barrier region. The third sensor terminal is formed in direct proximity to the electromigration barrier region at least partially parallel to the first test structure terminal region and has a smaller interconnect width than the electromigration region.

In particular through the use of a third sensor terminal, which is connected to the electromigration region in direct proximity to the electromigration barrier region, and such structuring of the electromigration region to the effect that an essentially homogeneous temperature distribution is produced therein, it is possible to make extraordinarily precise statements about the temperatures respectively present, as a result of which the current densities can be set and, depending on the quantitative statements about the temperature, an improved test accuracy is produced even when using contacts (vias), for example. As a secondary effect, it is thus possible, moreover, to carry out a simplified electrical error analysis for accurately determining a failure location.

The electromigration barrier region is preferably a contact and the electromigration region is a metallic interconnect having a constant width.

First and second test structure terminal regions preferably have a tapering toward the region to be tested, as a result of which it is possible to prevent the occurrence of mechanical stresses and a metal flow divergence on account of temperature differences and also an altered electromigration. The tapering is configured in essentially stepped fashion in this case, as a result of which a maximum and accurately predeterminable temperature gradient can be set given corresponding structuring or selection of the respective interconnect widths.

In order to further increase the test accuracy, the sensor terminals are configured in such a way with respect to the electromigration region and with respect to the test structure terminal region that a certain temperature compensation can take place and the influence of the sensor terminals is minimized. In this case, a second sensor terminal is preferably situated at the second test structure terminal region in the region of the tapering, as a result of which a temperature prevailing in the electromigration region remains virtually uninfluenced.

In order to further improve a respective product relevance, dummy structures may be formed essentially parallel to the region to be tested, as a result of which significantly more realistic structures are produced and, by way of example, a thermal dissipation to adjacent interconnects can be evaluated. The dummy structure preferably contains a dummy electromigration region and a dummy electromigration barrier region, as a result of which not only the interconnects but also the contacts (vias), for example, can be tested with regard to their product-relevant thermal behavior.

In accordance with an added feature of the invention, a cross-sectional area of the first and second test structure terminal regions, of the electromigration region and/or of the electromigration barrier region is configured such that a respective temperature gradient of at most a predetermined value exists when a temperature is reached.

In accordance with another feature of the invention, the dummy structure is spaced apart from the region to be tested with a minimum structure width.

In accordance with a further feature of the invention, the electromigration test structure is configured for highly accelerated tests with Joule heating.

Other features which are considered as characteristic for the invention are set forth in the appended claims.

Although the invention is illustrated and described herein as embodied in an electromigration test structure for detecting the reliability of wirings, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1A is a diagrammatic, plan view of an electromigration test structure in accordance with a first exemplary embodiment according to the invention;

FIG. 1B is a graph showing a temperature profile associated with the test structure in accordance with FIG. 1A;

FIG. 1C is a diagrammatic, sectional view taken along the line 1C-1C shown in FIG. 1A;

FIG. 1D is a partial view of the electromigration test structure in a region of an electromigration barrier region;

FIG. 2 is a simplified plan view of the electromigration test structure in accordance with a second exemplary embodiment; and

FIG. 3 is a partial sectional view of an electromigration barrier region in accordance with a third exemplary embodiment.

### DESCRIPTION OF THE PREFERRED EMBODIMENTS

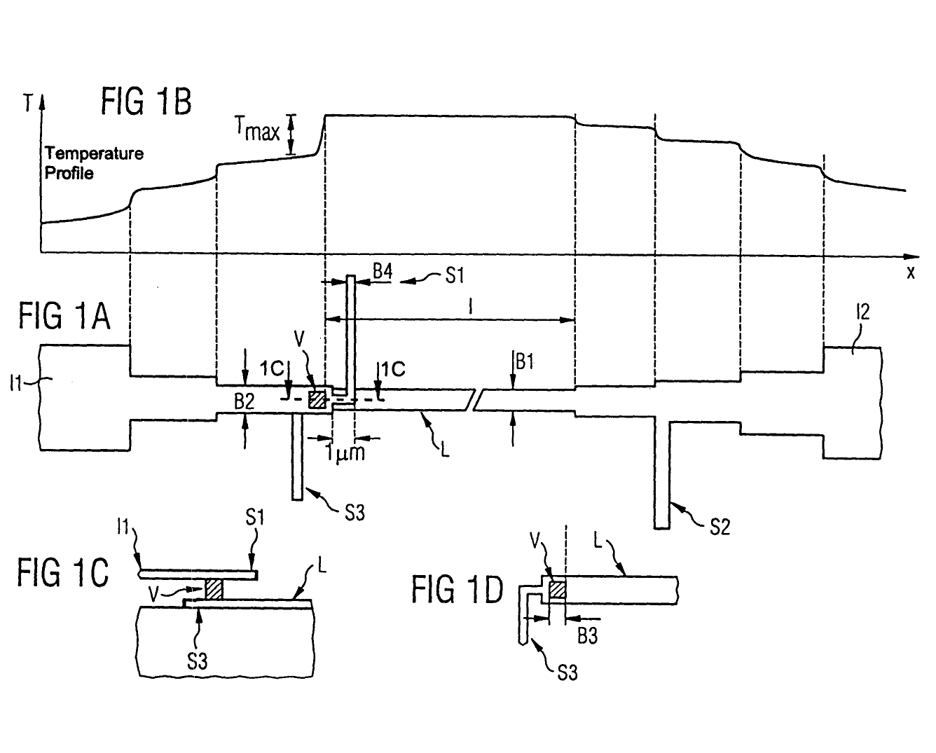

Referring now to the figures of the drawing in detail and first, particularly, to FIG. 1A thereof, there is shown a simplified plan view of an electromigration test structure in accordance with a first exemplary embodiment, a region to be tested having an electromigration region L and an electromigration barrier region V. More precisely, the electromigration region L contains, for example, a metallic interconnect having a width B1, which is formed, for example, in a metallization plane of an associated semiconductor circuit. Given a sufficient length l of the electromigration region L, a constant material flow caused by electromigration prevails at a constant temperature in the region.

In order to realize an electromigration barrier region V, in which a reduced material flow on account of electromigration prevails, the test structure in accordance with the first exemplary embodiment uses a contact (via) or contact hole V situated between the metallization plane for the electromigration region L and a further metallization plane for a first test structure terminal region I1. In the associated semiconductor circuit, such contacts (vias) produce respective connections between the individual metallization planes, but other materials are usually used and a reduced material flow on account of the electromigration effect therefore prevails. These regions therefore act as electromigration barriers.

FIG. 1C shows a simplified sectional view along section line 1C-1C shown in FIG. 1A. Identical reference symbols representing identical or corresponding elements and a repeated description being dispensed with below.

In accordance with FIG. 1C, the first terminal region I1 may have a first metallic interconnect composed, for example, of aluminum, copper, etc. In the same way, the electromigration region L formed in the underlying metallization plane may likewise have an aluminum, copper or some other metallic interconnect. The electromigration region realized as a contact (via) is composed, for example, of tungsten, titanium or some other electrically conductive material with good filling properties. On account of the different material, however, such contacts (vias) V act as electromigration barriers since no material of the same type is subsequently supplied and, consequently, at these places material is preferably transported away in the conducting plane, which may ultimately lead to the failure of the test structure.

In accordance with FIGS. 1A and 1C, a first sensor terminal S1 and a third sensor terminal S3 having a small interconnect width B4 are situated in direct proximity to the contact (via) V. The small interconnect width already makes it possible to minimize an influencing of a temperature of the region to be tested. Furthermore, a width B2 of the first test structure terminal region I1 at the contact (via) V is dimensioned with respect to the width B1 of the electromigration region L in such a way that the temperature gradient between the two planes on account of the Joule heating effected as a result of the impressed heating current does not become too high. Preferably, a temperature gradient between the first test structure terminal region I1 at the contact (via) V and the electromigration region L is set to <50° C., as a result of which mechanical stresses and influencing of the electromigration can be reliably minimized. In this case, current is impressed directly from the first test structure terminal region I1 to a second test structure terminal region I2, which adjoins the other end of the electromigration region L.

In order to further reduce a respective temperature gradient and the resultant material flow divergence to an actual terminal pad, the widths of the first and second test structure terminal regions I1 and I2 are in each case reduced stepwise (tapering), thereby producing a tapering toward the region to be tested. The cross-sectional areas of the respective interconnect sections are once again set in such a way that a maximum temperature gradient Tmax of e.g. 50° C. is produced and, consequently, in particular mechanical stresses between the steps are also avoided. A further advantage of the stepped form is the simple photolithographic structuring.

For the highly accurate determination of a temperature respectively generated in the electromigration region L, the second test structure terminal region I2 has a second sensor terminal S2, which, in accordance with FIG. 1A, by way of example, is formed only at the tapering or second step, thereby enabling further reduction of possible influencing of a temperature profile by the second sensor terminal S2. A width of the sensor terminal is once again kept as small as possible in order to prevent an undesirable temperature sink.

FIG. 1B shows a simplified illustration of a temperature profile along the test structure illustrated in FIG. 1A. What is essential in this case is that the temperature generated in the electromigration region L is extraordinarily homogeneous and can also be detected quantitatively very accurately by the sensor terminals S2 and S3, which is of importance particularly in the case of highly accelerated tests. With a test structure of this type, it is thus possible to obtain, on account of greatly increased current densities particularly in the electromigration region L, the strong heating and high temperatures resulting on account of Joule heating which lead to a significant shortening of the test times. In this case, the extraordinarily high temperatures in the electromigration region L are essentially constant and can be determined with high accuracy by the second and third sensor terminals S2 and S3 in order to drive respective test programs accordingly.

By way of example, for the purpose of determining temperature, a temperature dependence of the electromigration region L or an associated metal resistor is utilized in this case, the sensor terminals in each case serving as voltage taps for detecting a respective voltage drop or a potential difference across the electromigration region L. The simple structure of the electromigration region L with its sufficient length l and predetermined width B1 thus enables a simple and extremely exact determination of a respective interconnect temperature during the measurement, as a result of which adequate conclusions can be drawn with regard to the associated semiconductor circuit or thin-film circuit. In this case, the electromigration region L and the contact (via) correspond to typical interconnects and contacts (vias) in the associated semiconductor circuit.

Since the voltage terminals or taps S1 and S3 at the contact (via) can lead to undesirable cooling of the structure and in particular of the electromigration region L, in accordance with FIGS. 1A and 1D these sensor terminals S1 and S3 are led over a certain section or at least partly parallel to the electromigration region L or to the test structure terminal region I1, thus resulting in an optimization of the temperature profile. In the same way, the sensor terminal S2, too, is not formed directly but rather only after the first step in order to avoid undesirable temperature sinks at the second terminal region I2. Given corresponding dimensioning of the respective interconnect widths, mechanical stresses caused on account of temperature differences, in particular, can thus largely be prevented.

In accordance with FIGS. 1A and 1B, the widths B1, B2, B3 and B4 of the respective terminal regions I1 and I2 of the electromigration region L and of the electromigration barrier region V are dimensioned in such a way that when a respective test temperature is reached in the electromigration region L, a respective temperature gradient lies below a maximum predetermined value Tₘₐₓ (e.g. 50° C.). By virtue of the third sensor terminal S3, in particular, it is now also possible to carry out product-relevant reliability examinations (i.e. semiconductor circuits having contacts (vias) V) using highly accelerated test methods, it being possible to make extraordinarily accurate statements for example about a respective service life of semiconductor circuits or thin-film circuits. What is more, the further sensor terminal S3 now makes it possible also to electrically determine the precise failure location, as a result of which a respective cause of the failure can be determined. Consequently, complicated preparations and SEM examinations as have had to be carried out on conventional test structures in order to determine, for example, the precise location of the failure are no longer necessary.

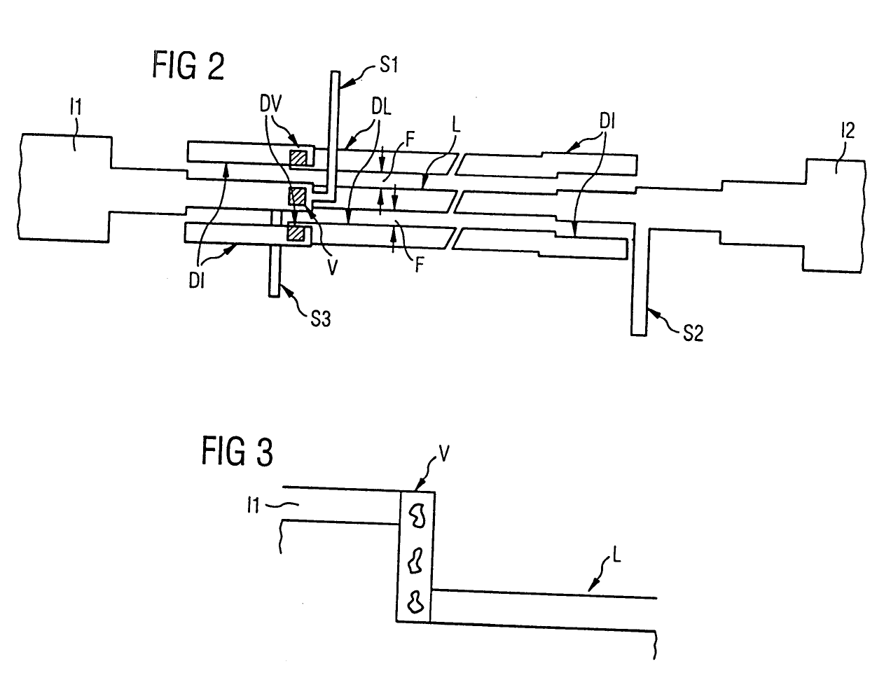

FIG. 2 shows a simplified plan view of an electromigration test structure in accordance with a second exemplary embodiment, identical reference symbols designating identical or corresponding elements and a repeated description being dispensed with below.

In accordance with FIG. 2, in a second exemplary embodiment, so-called dummy structures are formed parallel to the region to be tested, which essentially has the electromigration region L and the electromigration barrier region V, the dummy structures preferably being spaced apart at a distance F. In this case, F is a minimum structure width that can be realized lithographically in a respective production process.

Such a dummy structure formed at least with respect to the electromigration region L once again serves for increasing respective product relevance. Since, in particular, the imaging properties used in lithographic processes can image isolated or individual interconnects only in an unsharp manner and with highly indeterminate cross-sectional properties, the dummy structure illustrated in FIG. 2 enables adaptation to conditions actually prevailing, since the region to be tested essentially has the same structuring as an interconnect in the associated semiconductor or thin-film circuit. The occurrence of supercritical test structures that by way of example, fail earlier than the associated semiconductor circuit can thereby be prevented.

Accordingly, in accordance with FIG. 2, a dummy electromigration region or a respective dummy line DL is in each case formed parallel to the electromigration region L at the minimum permitted distance on both sides of the test structure. In addition to the above-described improved imaging properties in particular for the electromigration region L, it is thus also possible, however, to simulate the temperature conditions in an associated semiconductor circuit significantly better. More precisely, owing to their proximity to the test structure or to the electromigration region L, the dummy electromigration regions DL cool the latter down, that is why a higher current density becomes necessary for achieving the same test temperature. Since this current also flows through the electromigration barrier regions V and brings about heating therein, the dummy structures may also have respective dummy electromigration barrier regions DV or so-called dummy contacts (vias) in order to avoid corresponding overheating. A further improvement of the product relevance or of a thermal radiation to interconnects lying parallel can be realized by virtue of the dummy terminal regions DI—illustrated in FIG. 2—parallel to the first and second terminal regions I1 and I2. Accordingly, the dummy structure illustrated in FIG. 2 makes it possible to achieve a uniform cooling of the contact (via) V and of the conducting plane and enables the respective structure to be imaged in a manner that is as far as possible uniform and entirely satisfactory in terms of photo technology, thus yielding a very accurate statement about the respective product properties of an associated semiconductor circuit.

FIG. 3 shows a simplified partial sectional view of an electromigration test structure in accordance with a third exemplary embodiment in the region of the electromigration barrier V. Identical reference symbols once again designate elements identical or corresponding to those in FIGS. 1 and 2, for which reason a repeated description is dispensed with below.

In accordance with FIG. 3, an electromigration barrier with reduced material flow can also be produced for example by depositing a continuous metallic interconnect over a topography or edge, as a result of which, by way of example, on account of different deposition rates at the edge, different material structures are produced and a reduced material flow on account of the electromigration effect occurs. Accordingly, in accordance with the present invention, the electromigration test structure described above can be applied not only to the contacts (vias) described above but also to the electromigration barrier regions V illustrated in FIG. 3, thereby making it possible once again to realize a highly accurate and highly accelerated test of such structures. In the same way, in accordance with FIG. 3, by way of example, side wall contacts or connecting structures in trenches realized by spacer technology also come under the term electromigration barrier region.

The invention has been described above on the basis of integrated semiconductor circuits. However, it is not restricted thereto and encompasses in the same way electrical circuits configured using thin-film technology.

We claim:

1. An electromigration test structure for detecting reliability of wirings, comprising:
first and second test structure terminal regions for impressing a heating current;
a region to be tested having an electromigration region with a constant material flow and an electromigration barrier region with a reduced material flow, said region to be tested connected between said first and second structure terminal regions, said electromigration region structured for producing a substantially homogeneous temperature distribution therein;
first and second sensor terminals coupled to and detecting a failure of said region to be tested; and
a third sensor terminal for detecting a temperature of said electromigration region and connected to said electromigration region in direct proximity to said electromigration barrier region, said third sensor terminal formed in direct proximity to said electromigration barrier region at least partially parallel to said first test structure terminal region and having a smaller interconnect width than said electromigration region.

2. The electromigration test structure according to claim 1, wherein said electromigration barrier region is a contact.

3. The electromigration test structure according to claim 1, wherein said electromigration region is a metallic interconnect having a constant width.

4. The electromigration test structure according to claim 1, wherein said first and second test structure terminal regions each have a tapering toward said region to be tested.

5. The electromigration test structure according to claim 4, wherein said tapering is formed in a stepped fashion.

6. The electromigration test structure according to claim 1, wherein said first sensor terminal is configured such that a temperature equalization with respect to said electromigration region can take place.

7. The electromigration test structure according to claim 4, wherein said second sensor terminal is formed at said second test structure terminal region in a region of said tapering.

8. The electromigration test structure according to claim 1, wherein a cross-sectional area of at least one of said first and second test structure terminal regions, of said electromigration region and of said electromigration barrier region is configured such that a respective temperature gradient of at most a predetermined value exists when a temperature is reached.

9. The electromigration test structure according to claim 1, further comprising at least one dummy structure formed essentially parallel to said region to be tested.

10. The electromigration test structure according to claim 9, wherein said dummy structure has at least one of a dummy electromigration region, a dummy electromigration barrier region and a dummy terminal region.

11. The electromigration test structure according to claim 9, wherein said dummy structure is spaced apart from said region to be tested with a minimum structure width.

12. The electromigration test structure according to claim 1, further comprising a circuit selected from the group consisting of a semiconductor circuit and a thin-film circuit, said circuit containing said first and second test structure terminal regions, said region to be tested, said first, second and third sensor terminals.

13. The electromigration test structure according to claim 1, wherein the electromigration test structure is configured for highly accelerated tests with Joule heating.

14. An electromigration test structure for detecting reliability of wirings, a region to be tested having an electromigration region with a constant material flow and an electromigration barrier region with a reduced material flow, the electromigration region structured for producing a substantially homogeneous temperature distribution therein, the electromigration test structure comprising:
first and second test structure terminal regions for impressing a heating current, the region to be tested connected between said first and second structure terminal regions;
first and second sensor terminals coupled to and detecting a failure of the region to be tested; and
a third sensor terminal for detecting a temperature of the electromigration region and connected to the electromigration region in direct proximity to the electromigration barrier region, said third sensor terminal formed in direct proximity to the electromigration barrier region at least partially parallel to said first test structure terminal region and having a smaller interconnect width than the electromigration region.
